(19) United States
(12) Patent Application Publication
(10) Pub. No.: US 2014/0305504 A1
(43) Pub. Date: Oct. 16, 2014

(54) SOLAR CELL

(71) Applicants: Taizo Masuda, Yokohama-shi Kanagawa-ken (JP); Kenichi Okumura, Gotenba-shi Shizuoka-ken (JP); Junya Ota, Susono-shi Shizuoka-ken (JP)

(72) Inventors: Taizo Masuda, Yokohama-shi Kanagawa-ken (JP); Kenichi Okumura, Gotenba-shi Shizuoka-ken (JP); Junya Ota, Susono-shi Shizuoka-ken (JP)

(73) Assignee: TOYOTA JIDOSHA KABUSHIKI KAISHA, Toyota-shi Aichi-ken (JP)

(21) Appl. No.: 14/243,678

(22) Filed: Apr. 2, 2014

(30) Foreign Application Priority Data
Apr. 12, 2013 (JP) 2013-083757

(51) Int. Cl. H01L 31/0236

(52) U.S. Cl. CPC H01L 31/02366
USPC 136/261; 136/252

(57) ABSTRACT

A high voltage output solar cell which is small in size and high in power generation efficiency is provided. The solar cell is provided with a p-type or n-type monocrystalline semiconductor substrate (1) forming a power generation layer, a plurality of hole collecting layers (2), electron collecting layers (3), and grooves (7) provided inside of the semiconductor substrate (1) contiguous to a back surface which faces a light receiving surface of the semiconductor substrate (1), hole collecting layers (2) and electron collecting layers (3) being provided between adjoining grooves (7) and hole collecting layers (2) and electron collecting layers (3) being provided sandwiching grooves (7), and interconnect layers (8) which connect hole collecting layers (2) and electron collecting layers (3) sandwiching grooves (7), the grooves (7) being formed from the back surface side toward the inside of semiconductor substrate (1).

### FIELD

The present invention relates to a solar cell, more particularly relates to a solar cell which can form a high voltage output by a single cell.

### BACKGROUND

In general, the output voltage of a solar cell is low. Therefore, usually, the practice is to serially connect a plurality of solar cells to obtain the desired output voltage. Japanese Patent Publication No. 2006-156663 describes a solar battery which connects a plurality of solar cells in series to obtain a high voltage output. On the other hand, when a plurality of solar cells cannot be arrayed, that is, when the installation area is small such as on the roof of a vehicle, and it is necessary to place a solar battery to obtain a high voltage output, a single commercially available solar cell has been separated into a plurality of small cells and the separated small cells have been connected in series to try to obtain the desired high voltage output.

FIG. 10A shows a commercially available single solar cell 100 (156 mm×156 mm) with an output voltage of 0.7V. If physically separating this solar cell 100 into, for example, 12 small cells 200, 200 . . . and using interconnects such as shown in FIG. 10B to connect them in series, it is possible to construct a solar cell panel with a 0.7×12=8.4V output voltage. The solar cell 100 is cut into individual small cells mechanically using a circular blade.

However, the solar cell panel which is configured such as in FIG. 10B has the following problems: That is, a) there are spaces between the adjoining small cells 200, so it is not possible to effectively utilize that portion of the solar energy. When producing the solar cell panel (when laminating it), the protective material (EVA or rubber or other such material) which surrounds the cells contracts by heat, so it is necessary to provide spaces between adjoining cells. If there were no spaces, the adjoining cells would interfere with each other and the cells would be damaged. For this reason, the space between cells is for example made 2 mm or so. If this space is not provided, production of solar cell panels with a low reject rate becomes difficult.

Furthermore, b) physically cutting a single solar cell into a plurality of small cells 200 causes the cell area to drop and the amount of power generation to fall by that amount, so the cost of manufacturing a solar cell panel for obtaining the desired output power increases. The cell is cut mechanically by using a circular blade, so the cell area falls by at least the blade thickness (tens of μm). The greater the number of parts separated into, the greater that effect.

Further, c) as shown in FIG. 11, when connecting the small cells 200 in series, the individual cells deviate in position and the appearance becomes poor. As explained above, when producing a solar cell panel, the protective material which surrounds the cells contracts under heat. Along with that contraction, the cells also end up moving somewhat. The heat contraction occurs in random directions, so the cells deviate in position. The larger the number of cells which are connected, the more noticeable the positional deviation of the cells which have moved slightly. The appearance becomes extremely poor.

### SUMMARY

As explained above, in a solar cell panel which is obtained by separating a single solar cell into a plurality of cells and connecting them in series to obtain a high voltage output, there are the problems that due to the drop in the efficiency of utilization of solar energy, the physical reduction in the cell areas, etc., the cost for obtaining a predetermined amount of power generation increases and the appearance becomes poor. Therefore, the object of the present invention is to provide a solar cell which can give a high voltage output without separating the solar cell.

To achieve the above object, in a first aspect of the present invention, there is provided a solar cell which is provided with a p-type or n-type monocrystalline semiconductor substrate which forms a power generation layer, a plurality of hole collecting layers, electron collecting layers, and grooves which are provided inside of the semiconductor substrate contiguous to a back surface which faces a light receiving surface of the semiconductor substrate, the hole collecting layers and the electron collecting layers being provided between adjoining grooves and the hole collecting layers and the electron collecting layers being provided sandwiching the grooves, and interconnect layers which connect the hole collecting layers and the electron collecting layers sandwiching the grooves, the grooves being formed from the back surface side toward the inside of the semiconductor substrate.

In the solar cell of the first aspect, high concentration doped layers with doped concentrations of predetermined values or more may be formed in accordance with the conductivity types of the power generation layer between the light receiving surface of the semiconductor substrate and the bottoms of the grooves. Further, low concentration doped layers with carrier concentrations lower than the carrier concentrations of the power generation layer may be formed between the light receiving surface of the semiconductor substrate and the bottoms of the grooves. Furthermore, a light receiving surface side of the semiconductor substrate may be formed with diffusion layers with different conductivity types between the adjoining grooves.

Still further, insulating films may be formed at surfaces of the grooves. The grooves have to have a depth of three-fourths of the thickness of the semiconductor substrate. The power generation layer may be formed using Si, Ge, C, SiGe, and SiC as a material.

In the solar cell of the present invention, it is possible to obtain a high voltage output without separating a cell into a plurality of small cells. For this reason, it is possible to generate power while utilizing all of the light receiving area inherently possessed by the cell without detracting from it, so it is possible to obtain a high power generation efficiency. Further, along with this, the cost of manufacture of the solar cell panel decreases. Furthermore, since a single cell can be used to achieve a high voltage output, it becomes possible to form a beautiful appearance solar cell panel free of the problems of positional deviation of cells which occurs when arranging a plurality of cells together.

Note that, the grooves which separate the solar cell into a plurality of regions never reach the front surface of the solar cell. Therefore, non-separated regions remain between the solar cell surface and bottom of the grooves, but these parts are, for example, provided with high concentration impurity doped layers, low carrier concentration layers, or diffusion layers of different conductivity types at the left and right of the non-separated regions whereby movement of carriers between regions through the non-separated regions is prevented and a drop in power generation efficiency is prevented. Further, by providing insulating films on the surfaces of the grooves, even when the solar cell is bent due to the requirements of the installation location etc., short-circuits due to contact of adjoining regions with each other can be prevented.

The present invention may be more fully understood from the description of the preferred embodiments according to the invention as set forth below, together with the accompanying drawings.

### BRIEF DESCRIPTION OF THE DRAWINGS

FIG. 1 is a cross-sectional view of a back surface electrode type solar cell.

FIG. 2 is a cross-sectional view of a solar cell according to an embodiment of the present invention.

FIG. 3 is a plan view of a solar cell which is shown in FIG. 2.

FIG. 4 is a plan view of a modification of a solar cell which is shown in FIG. 1.

FIG. 5 is a cross-sectional view of a solar cell according to another embodiment of the present invention.

FIG. 6 is a view which shows enlarged part of a solar cell which is shown in FIG. 5.

FIG. 7 is a cross-sectional view which shows a modification of the embodiment which is shown in FIG. 5.

FIG. 8 is a cross-sectional view of a solar cell according to still another embodiment of the present invention.

FIG. 9 is a view which explains the advantageous effect of the solar cell which is shown in FIG. 8.

FIG. 10A is a plan view of a conventional solar cell.

FIG. 10B is a schematic view which shows a high output solar cell panel which is comprised of the solar cells of FIG. 10A.

FIG. 11 is a view which shows positional deviation of cells in the solar cell panel which is shown in FIG. 10B.

### DESCRIPTION

Below, various embodiments of the present invention will be explained with reference to the drawings. Note that, in the figures which are shown below as a whole, the same reference notations show the same or similar components and overlapping explanations are not given. Furthermore, the figures are meant only for explaining the present invention. Therefore, the sizes of the components in the figures do not correspond to the actual scale.

### First Embodiment

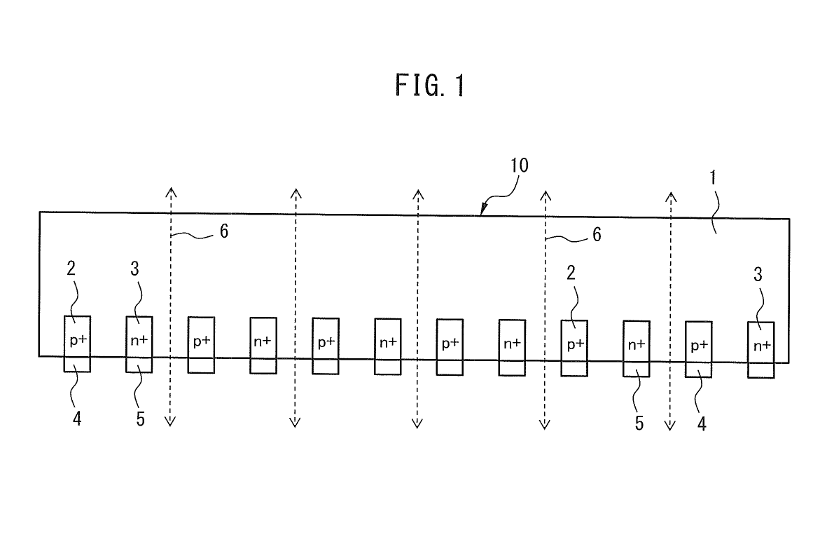

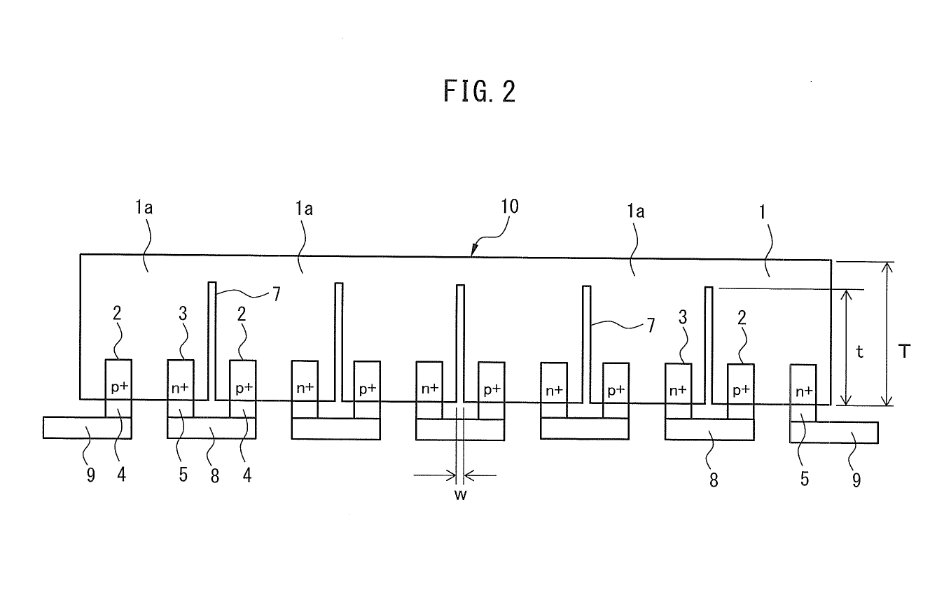

The structure of a back surface electrode type solar cell 10 according to a first embodiment of the present invention will be explained with reference to FIGS. 1 and 2. FIG. 1 is a cross-sectional view of a solar cell which for example provides a power generation layer 1 which is comprised of an n-type monocrystalline semiconductor substrate of Si with a plurality of pairs of p⁺ diffusion layers 2 which function as hole collecting layers and n⁺ diffusion layers 3 which function as electron collecting layers and provide the diffusion layers 2, 3 with positive electrodes 4 or negative electrodes 5. In this state of solar cell, in the past the solar cell was physically cut along the dividing lines 6 to form a plurality of small cells with equal areas. These were connected in series to form a solar cell panel which provided a high voltage output.

As opposed to this, the solar cell 10 of the present embodiment, as shown in FIG. 2, is characterized by providing grooves 7 which do not reach the front surface of the power generation layer at the positions of the dividing lines 6 to thereby partition and physically separate the power generation layer 1 into a plurality of equal volume regions 1a. The grooves 7 are formed leaving at least about one-fourth of the layer thickness of the power generation layer 1 from the solar cell surface (light receiving surface). To completely separate the adjoining regions 1a, 1a, the grooves 7 are preferably formed up to close to the front surface of the power generation layer 1, but to secure the mechanical strength of the solar cell 10 as a whole, it is necessary to leave a certain extent of non-separated regions, for example, about one-fourth of the layer thickness of the power generation layer 1.

In the illustrated embodiment, for example, in a solar cell which overall has a size of 156 mm×156 mm, when the thickness (T) of the power generation layer 1 is 150 μm, the depth (t) of the grooves 7 from the back surface is made about 100 μm and the width (w) is made about 1 μm.

In FIG. 2, 8 show interconnect layers which use Al etc. as a material. They are provided to serially connect the regions 1a of the power generation layer 1 by serially connecting the positive electrodes and negative electrodes 5 between the adjoining regions 1a, 1a. Reference numeral 9 shows takeout electrodes for connection with other solar cells or devices. The positive electrodes 4, negative electrodes 5, interconnect layers 8, and takeout electrodes 9 are, for example, formed using Al as a material.

The grooves 7 can be easily formed by for example dry etching the solar cell 10 in the state of FIG. 1 from the back surface side (opposite side to light receiving surface). For forming the etching pattern, for example, a lithographic process may be utilized. Note that, the regions (non-separated regions) which remain unseparated between the bottoms of the grooves 7 and light receiving surface of the power generation layer 1 are preferably a single monocrystal, but the regions may also be connected in a polycrystalline state.

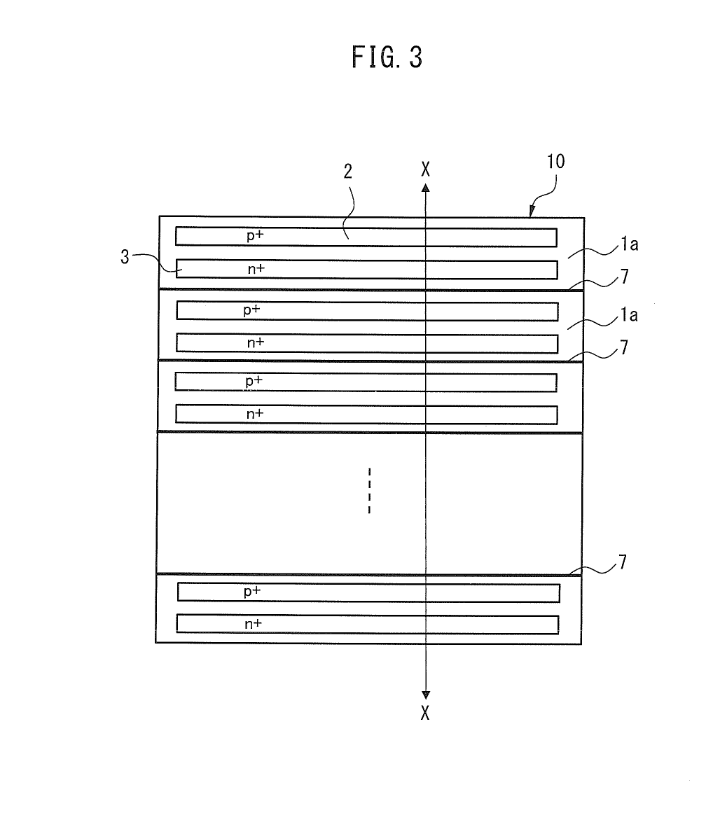

FIG. 3 is a plan view which views the solar cell 10 according to the present embodiment from the back surface side, but here the positive and negative electrodes 4, 5, interconnect layers 8, and takeout electrodes 9 are omitted from the illustration. As shown in FIG. 3, in the solar cell 10 of the present embodiment, the plurality of regions 1a which have pairs of p⁺ diffusion layers 2 and n⁺ type diffusion layers 3 are delineated by the grooves 7. The grooves 7, as shown in the figure, are formed cutting across the horizontal width of the solar cell 10. Further, five are formed in parallel in the direction of the vertical width. For this reason, the solar cell 10 is separated into six regions of substantially 25 mmX156 mm size.

While not shown in FIG. 3, the p⁺ diffusion layers 2 and n⁺ diffusion layers 3 which adjoin each other through the grooves 7 are connected by the interconnects 8 (see FIG. 2), whereby six regions 1a are connected inside one solar cell 10. As a result, for example, 0.7×6=4.2V of output can be obtained. In this way, in the solar cell of the present embodiment, it is possible not to physically cut the cell to separate it and to obtain a high voltage output by the size of a single cell.

Note that, FIG. 2 corresponds to a cross-section on the line X-X of FIG. 3. Further, in general, sometimes the front surface of the power generation layer 1 (light receiving surface) is provided with a passivation layer, reflection prevention layer, etc., but these are omitted since they have no direct bearing in the explanation of the configuration of the present invention.

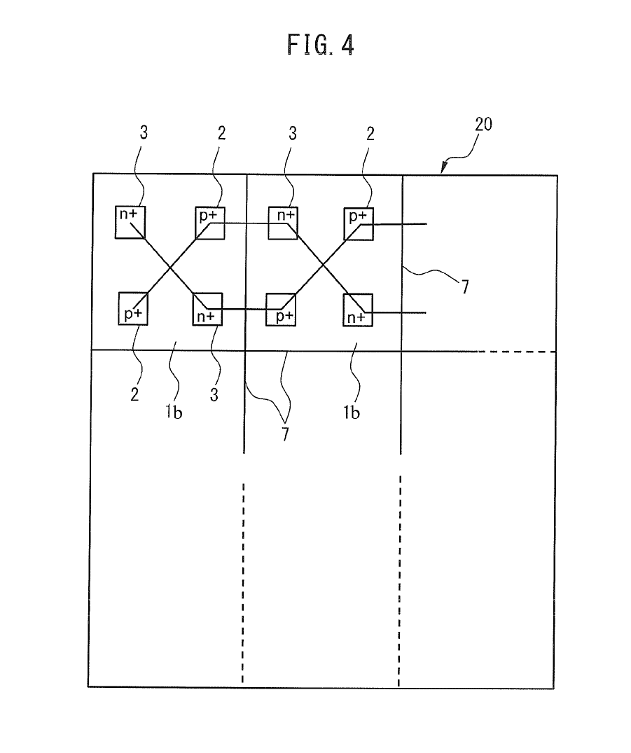

FIG. 4 is a schematic view which shows a modification of the first embodiment of the present invention. This solar cell 20 is an example where a solar cell is separated by a plurality of vertical and horizontal grooves 7 into equal areas. If connecting the adjoining regions 1b, 1b separated by the grooves 7 so that the p⁺ diffusion layers 2 and the n⁺ diffusion layers 3 are connected in series, it is possible to form a high voltage output in accordance with the number of the connected regions. Note that, there are various patterns for formation of grooves 7. The invention is not limited to those which are shown in FIGS. 3 and 4.

In the above way, in the solar cell according to the first embodiment of the present invention, unlike the conventional device, high voltage output is achieved without physically separating one cell into a plurality of small cells, so it is possible to effectively utilize solar energy without light receiving loss. Furthermore, it is not necessary to physically arrange a plurality of small cells to form a high voltage output panel, so there is no deterioration of appearance due to positional deviation.

### Second Embodiment

In the solar cell according to the first embodiment of the present invention which is shown in FIG. 2, the adjoining regions 1a, 1a (or 1b, 1b) were separated by grooves 7, but non-separated regions remained between the bottoms of the grooves 7 and the light receiving surface of the power generation layer 1 so these were electrically connected. For this reason, while slight, carriers moved between adjoining regions through these non-separated regions. The adjoining regions 1a, 1a of the present invention are connected in series, so unless the balance of current (carriers) is constant at the different regions, the smallest current in the regions will become an influencing factor and as a result the overall amount of power generation will fall. The solar cell according to the second embodiment was made in consideration of this point and is characterized by provision of a mechanism which limits the carrier movement between adjoining regions.

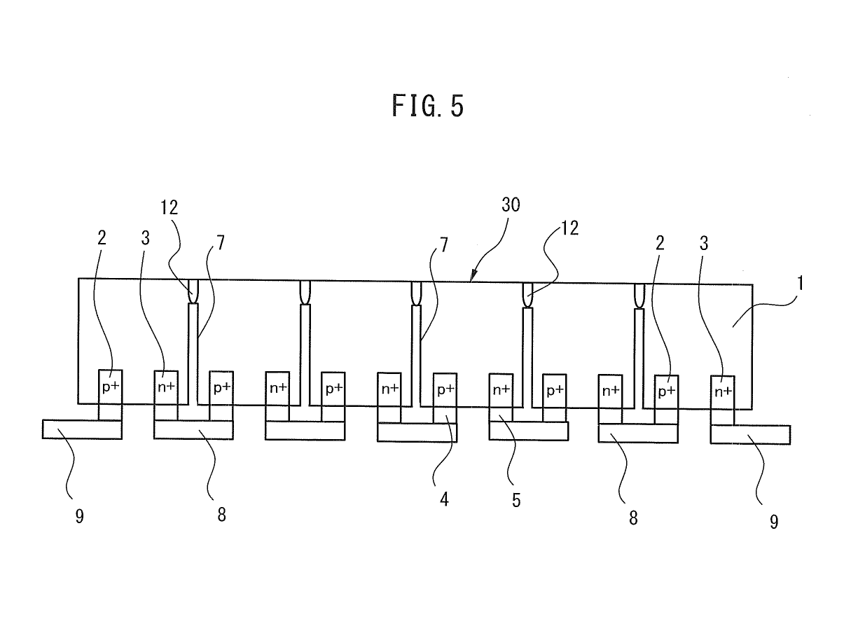

FIG. 5 is a cross-sectional view of a solar cell according to the second embodiment of the present invention. The solar cell 30 of the present embodiment, as shown in the figure, provides the non-separated regions between adjoining regions with high concentration doped layers 12 of n-type or p-type impurities so as to suppress carrier movement between adjoining regions and prevent a drop in the amount of power generation. The high concentration doped layers 12 have depths of extents reaching the bottoms of the grooves 7. Further, the widths are preferably not more than the widths of the grooves 7. The doped concentrations may be made values higher than the power generation layer 1 when the high concentration doped layer 12 has a conductivity type the same as the power generation layer 1 and may be made certain extents or more, for example, 1×10¹⁵ cm⁻³ or more, when the high concentration doped layer 12 has a conductivity type reverse from the power generation layer 1.

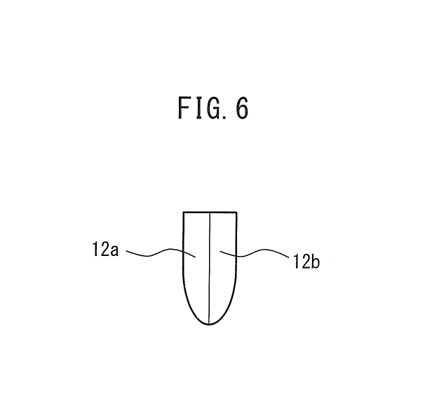

Further, the high concentration doped layer 12, as shown in FIG. 6, may be formed to have a set of a p-type region 12a and n-type region 12b. Furthermore, it is desirable to provide high concentration doped layers 12 for all of the grooves 7 of the solar cell 30, but if there is at least one high concentration doped layer 12 present, there is an effect of suppression of carrier movement between the adjoining regions 1a, 1a.

Note that, in the structure of FIG. 5, instead of providing the high concentration doped layers 12, it is also possible to provide low carrier concentration layers (i-layer). The low carrier concentration layers have a lower carrier concentration than the carrier concentration of the power generation layer 1. The lower the carrier concentration, the higher that part in resistance value and the greater the effect of prevention of carrier movement. The depths, widths, etc. of the low carrier concentration layers are the same extents as the high concentration doped layers 12 of FIG. 5.

A solar cell 30 which has the high concentration doped layers 12 or low carrier concentration layers is formed, for example, by forming between the front surface and back surface side of the power generation layer 1 a protective layer constituted by a SiO₂ layer by plasma CVD, etching the parts of the SiO₂ layer for forming the high concentration doped layers 12 etc. into patterns by utilizing a photolithography process etc., then heating this in a sealed container which is filled with n-type or p-type dopant gas. For the dopant gas, when the layers which are formed are the n-type, phosphine is utilized, while when the layers are the p-type, diborane etc. are utilized. The doping concentration and the diffusion depth can be made the desired values by controlling the heating temperature and gas concentration. When forming a low carrier concentration layer, doping gas which has a polarity reverse to the power generation layer is utilized. The high concentration doped layer 12 or low carrier concentration layer may be formed before forming the grooves 7 or after forming the grooves 7.

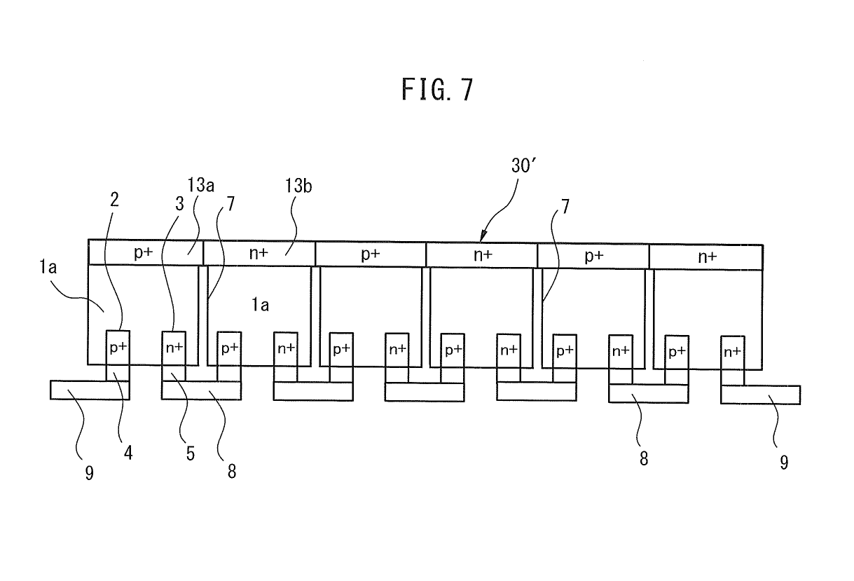

FIG. 7 is a view which shows a modification of the second embodiment. In this solar cell 30′, in the regions 1a which are separated by the grooves 7, the surface parts of the adjoining regions are provided with p⁺ type diffusion layers 13a and n⁺ type diffusion layers 13b. The p⁺ type diffusion layers 13a and n⁺ type diffusion layers 13b have depths of the same extents as the depths of the parts at which the adjoining regions 1a are connected (non-separated regions). In this solar cell 30′, energy barriers are formed at the non-separated regions so as to prevent carrier movement between adjoining regions, so a drop in the amount of power generation is prevented.

### Third Embodiment

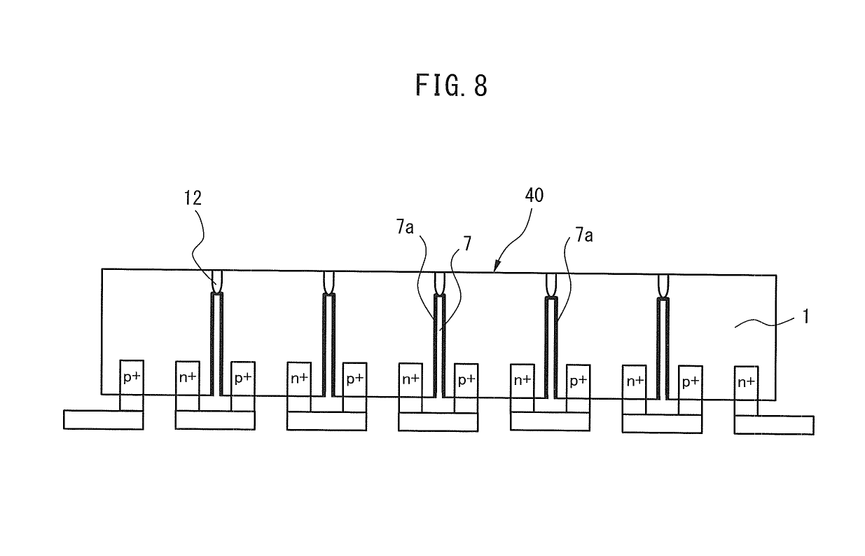

FIG. 8 is a cross-sectional view of a solar cell 40 according to a third embodiment of the present invention. The solar cell 40 of the present embodiment provides the solar cell 30 which is shown in FIG. 5 characterized in that the surfaces of the grooves 7 are formed with insulating films 7a. The insulating films 7a, for example, use as a material glass which contains boron or phosphorus, SiO₂, SiNₓ, a resin, etc.

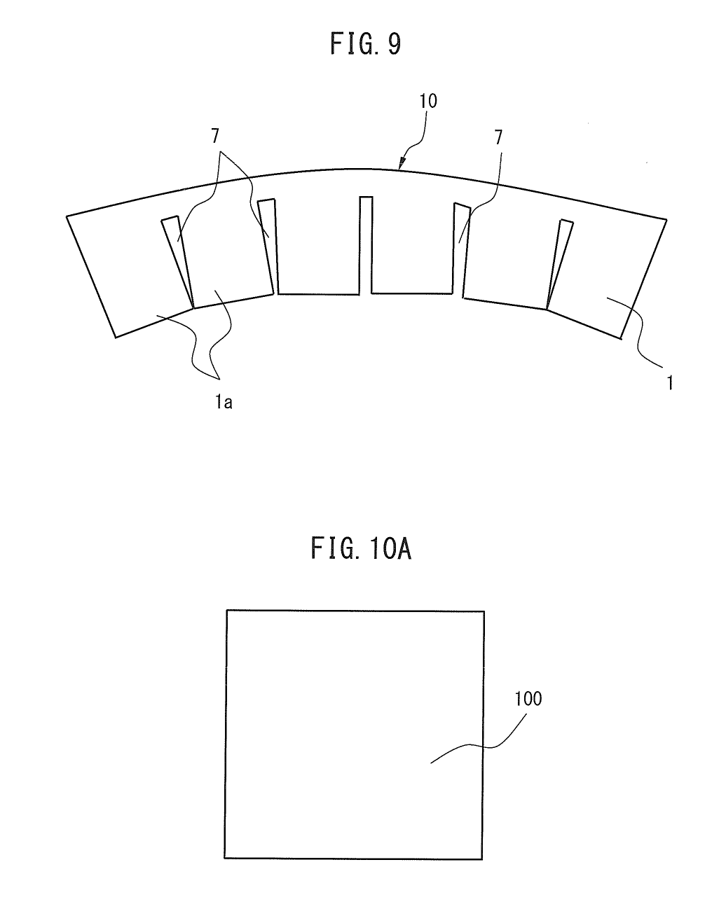

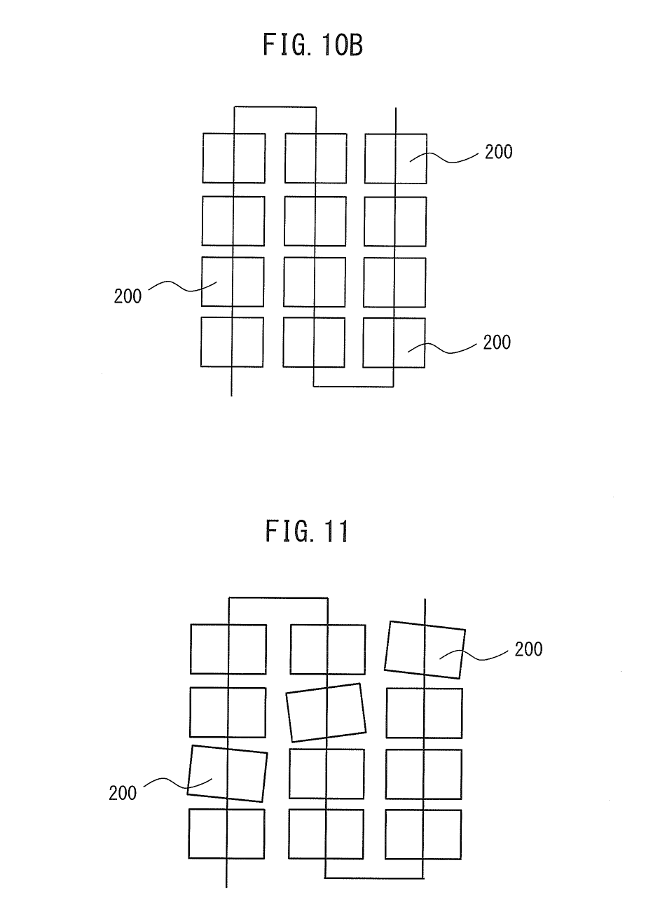

FIG. 9 shows the case of, for example, installing the solar cell 10 which is shown in FIG. 2 etc. on the roof of a vehicle. The roof of a vehicle is formed into a curved surface rather than a flat surface. If forming the solar cell 10 into a roof shape so as to install it there, the amount of deformation at the back surface side will be greater than at the front surface side and the adjoining regions 1a will sometimes end up contacting each other at the back surface side. In a back surface electrode type solar cell, power is generated mainly near the back surface, so if the adjoining regions contact each other near the back surface, short-circuited states will be caused and as a result the amount of power generation will greatly fall or no power at all will be generated any longer. In the solar cell 40 of the embodiment which is shown in FIG. 8, such a situation is prevented by forming insulating films 7a at the surfaces of the grooves 7.

The insulating films 7a can, for example, be formed by the following method: That is, when the insulating films 7a are glass which contain boron or phosphorus, the glass layers are formed by coating liquid solid layer diffusion sources on the surfaces of the grooves 7 and heat treating them to cause the organic binder to evaporate and thereby be removed. Further, when the insulating films 7a are SiO₂, the etching surfaces are heat treated in a water vapor atmosphere so as to form SiO₂ films on the surfaces of the grooves 7. When the insulating films 7a are SiNₓ, plasma CVD is used to deposit and form SiNₓ on the etching surfaces. When the insulating films 7a are resin films, resin which is dissolved in an organic solvent is coated on the etching surfaces, then these are heated to evaporate away the organic solvent and form resin layers on the surfaces of the grooves 7.

Note that, in the embodiment which is shown in FIG. 8, high concentration doped layers 12 were provided between the grooves 7 and the surface of the power generation layer 1, but the present embodiment which forms the insulating films on the surfaces of the grooves 7 can of course be applied to any of the solar cells according to the present invention which are for example shown in the other figures.

Further, in the above embodiments, the example was shown of use of Si as the material for the power generation layers which form the solar cells, but the present invention may be similarly worked by Ge, C, SiGe, SiC, etc. as well.

Furthermore, in the above embodiments, a single solar cell was provided with a plurality of grooves 7, but the present invention can also be worked by providing a single solar cell with a single groove. For example, by forming a single groove 7 at the center in the vertical direction or horizontal direction of a cell, it is possible to form a device which gives double the output voltage of an ordinary solar cell. Therefore the present invention can also be applied to the case of a single groove 7.

While the invention has been described by reference to specific embodiments chosen for purposes of illustration, it should be apparent that numerous modifications could be made thereto, by those skilled in the art, without departing from the basic concept and scope of the invention.

This application claims the benefit of JP Application No. 2013-83757, the entire disclosure of which is incorporated by reference herein.

What is claimed is:

1. A solar cell comprising:
a p-type or n-type monocrystalline semiconductor substrate which forms a power generation layer,
a plurality of hole collecting layers, electron collecting layers, and grooves which are provided inside of said semiconductor substrate contiguous to a back surface which faces a light receiving surface of said semiconductor substrate,
said hole collecting layers and said electron collecting layers being provided between adjoining grooves and said hole collecting layers and said electron collecting layers being provided sandwiching said grooves, and
interconnect layers which connect said hole collecting layers and said electron collecting layers sandwiching said grooves,
said grooves being formed from said back surface side toward the inside of said semiconductor substrate.

2. The solar cell according to claim 1, further comprising high concentration doped layers with doped concentrations of predetermined values or more formed in accordance with the conductivity types of said power generation layers between the light receiving surface of said semiconductor substrate and the bottoms of said grooves.

3. The solar cell according to claim 1, further comprising low concentration doped layers with carrier concentrations lower than carrier concentrations of said power generation layer, said low concentration doped layers being formed between the light receiving surface of said semiconductor substrate and the bottoms of said grooves.

4. The solar cell according to claim 1, further comprising diffusion layers with different conductivity types formed between said adjoining grooves at a light receiving surface side of said semiconductor substrate.

5. The solar cell according to claim 1, further comprising insulating films formed at surfaces of said grooves.

6. The solar cell according to claim 1, wherein said grooves are formed to a depth of three-fourth of a thickness of said semiconductor substrate.

7. The solar cell according to claim 1, wherein said semiconductor substrate is formed using Si, Ge, C, SiGe, and SiC as a material.
